(19) United States
(12) Patent Application Publication
(10) Pub. No.: US 2025/0137147 A1
(43) Pub. Date: May 1, 2025

(54) METHOD FOR MANUFACTURING MOS2-NI ELECTRODE USING CO-SPUTTERING

(71) Applicant: Korea Institute of Energy Technology, Naju-si (KR)

(72) Inventors: Chang Hee KIM, Naju-si (KR); Wan Sik KIM, Naju-si (KR); Jun Seok SIM, Naju-si (KR); Young Han JUNG, Naju-si (KR); Bong Hyun KIM, Gwangju (KR)

(73) Assignee: Korea Institute of Energy Technology, Naju-si (KR)

(21) Appl. No.: 18/928,349

(22) Filed: Oct. 28, 2024

(30) Foreign Application Priority Data
Oct. 30, 2023 (KR) 10-2023-0146956

(51) Int. Cl. C25B 11/075; C25B 11/031; C25B 11/061

(52) U.S. Cl. CPC C25B 11/075; C25B 11/031; C25B 11/061

(57) ABSTRACT

The present disclosure relates to a MoS2-Ni electrode and, in more detail, to a method for manufacturing an alkaline electrolysis electrode through co-sputtering, improves a 1T structure yield through a single process, and provides an electrolysis electrode with high activity in alkaline water electrolysis.

### CROSS REFERENCE TO RELATED APPLICATION

The present application claims priority to Korean Patent Application No. 10-2023-0146956, filed on Oct. 30, 2023, the entire contents of which are incorporated herein for all purposes by this reference.

### BACKGROUND

### Technical Field

The present disclosure relates to a MoS₂—Ni electrode and, in more detail, to a method for manufacturing an alkaline electrolysis electrode through co-sputtering.

### Description of the Related Art

As methods of forming a 1T structure of MoS₂ in the related art, there are electrochemical and physical delamination, surface treatment, physical deformation (strain effect), transition metal doping, etc.

The method using electrochemical and physical delamination, which is a well known method, is to perform delamination on MoS₂ using lithium (Li) atoms and can ensure a high 1T yield, but has a problem that it is difficult to be applied for a area and large has difficulty in commercialization of actual electrodes as a nano-scale process. The method using surface treatment involves techniques such as plasma and Ar gas treatment to induce deformation of Mo—S bond, thereby forming a 1T structure, but has a problem that the 1T yield is low as 15 to 50%.

The method using physical deformation ensures a 1T structure through structural deformation by applying physical force to a target material ((2H MOS₂ sheets) and has a high 1T structure yield, but can ensure excellent performance only when applying deformation of 10 to 11% to generate structural deformation. However, there is only a result by calculation and it is practically difficult to maintain a structure by applying strain over 10% to a molecular structure and there is a limitation in application to a bulky electrode.

The method using transition metal doping, which ensures a 1T structure by generating a gliding effect on the S atomic plane by doping 2H MOS₂ with transition metal, can ensure various 1T yields, depending on transition metal and uses hydrothermal synthesis for such doping, but has a problem that multiple steps are required and the cost is increased in electrodeionization back from a powder type.

### SUMMARY

An objective of the present disclosure is to improve a 1T structure yield through a single process and provide an electrolysis electrode with high activity in alkaline water electrolysis.

In order to achieve the objectives, a method for manufacturing an electrode using co-sputtering according to an embodiment of the present disclosure includes: preparing a substrate in a chamber; preparing MoS₂ and Ni as sputter targets in the chamber; pre-sputtering the sputter targets; and simultaneously depositing the sputter targets on the substrate.

The substrate may be Ni foam or Ni coin.

The sputter target MoS₂ and the sputter target Ni may be different in power supply type.

Power may be supplied in an RF type for the sputter target MOS₂.

Power may be supplied in a DC type for the sputter target Ni

Power of the sputter target MoS₂ may be 100 to 300 W.

Power of the sputter target Ni may be 5 to 50 W.

Time for the simultaneous deposition may be 1 to 5 hours (hr).

The present disclosure has effects of being able to provide an alkaline electrolysis electrode having a 1T structure through Ni doping and improve hydrogen evolution reaction activity and dynamic operation responsiveness in alkaline water electrolysis.

Further, the present disclosure has effects of being able to manufacture an electrode through a single process using co-sputtering, easily control the doping amount of elements, and achieve a large-area electrode.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a view showing the apparatus structure in a chamber for co-sputtering according to an embodiment of the present disclosure;

FIG. 2 shows surface SEM images of electrodes manufactured through co-sputtering according to an embodiment of the present disclosure;

FIG. 3 shows surface SEM images of electrodes manufactured through co-sputtering according to an embodiment of the present disclosure;

FIG. 4 shows an XRD analysis result of an electrode manufactured through co-sputtering according to an embodiment of the present disclosure;

FIGS. 5A and 5B show an XPS analysis result of an electrode manufactured through co-sputtering according to an embodiment of the present disclosure;

FIG. 6 shows an XPS analysis result of an electrode manufactured through co-sputtering according to an embodiment of the present disclosure;

FIGS. 7A to 7C show HR-TEM images of electrodes manufactured through co-sputtering according to an embodiment of the present disclosure;

FIGS. 8A to 8C show SAED images of electrodes manufactured through co-sputtering according to an embodiment of the present disclosure;

FIGS. 9A to 9C show ECSA analysis results of electrodes manufactured through co-sputtering according to an embodiment of the present disclosure;

FIG. 10 shows an ECSA analysis result of an electrode manufactured through co-sputtering according to an embodiment of the present disclosure;

FIGS. 11A to 11C show ECSA analysis results of electrodes manufactured through co-sputtering according to an embodiment of the present disclosure;

FIG. 12 shows an ECSA analysis result of an electrode manufactured through co-sputtering according to an embodiment of the present disclosure;

FIGS. 13A to 13C show hydrogen evolution reaction (HER) analysis results of electrodes manufactured through co-sputtering to an according embodiment of the present disclosure;

FIGS. 14A to 14C show HER (hydrogen evolution reaction) analysis results of electrodes manufactured through co-sputtering according to an embodiment of the present disclosure;

FIGS. 15A to 15C show HER (hydrogen evolution reaction) analysis results of electrodes manufactured through co-sputtering according to an embodiment 41 of the present disclosure;

FIG. 16 shows an overvoltage analysis result of an electrode manufactured through co-sputtering according to an embodiment of the present disclosure;

FIG. 17 shows an overall electrochemical analysis result of an electrode manufactured through co-sputtering according to an embodiment of the present disclosure;

FIG. 18 shows a cell voltage analysis result of a single cell using an electrode manufactured through co-sputtering according to an embodiment of the present disclosure;

FIG. 19 shows a cell voltage analysis result of a single cell using an electrode manufactured through co-sputtering according to an embodiment of the present disclosure; and

FIG. 20 shows a load variation analysis result of a single cell using an electrode manufactured through co-sputtering according to an embodiment of the present disclosure.

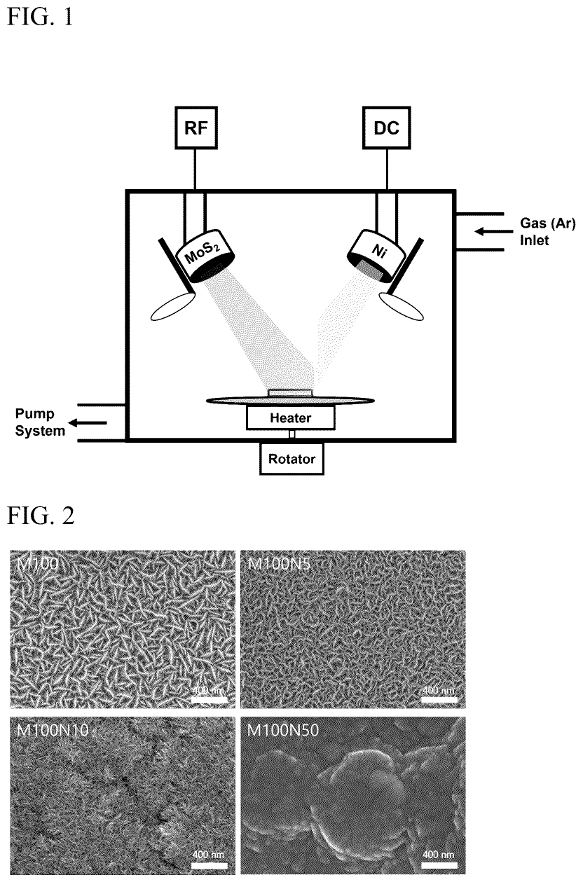

### DETAILED DESCRIPTION

Hereafter, embodiments of the present disclosure will be described in detail so that those skilled in the art can easily achieve the present disclosure. However, the present disclosure may be modified in various different ways and is not limited to the embodiments described herein.

A method for manufacturing an electrode through co-sputtering according to an embodiment of the present preparing a substrate in a chamber; disclosure includes: preparing MoS₂ and Ni as sputter targets in the chamber; pre-sputtering the sputter targets; and simultaneously the sputter targets on the substrate.

The substrate may be washed through sonication to remove an oxide film and impurities on the substrate before it is put (prepared) into the chamber and the washing may use KOH, HCL, or DI water. In this case, a KOH solution, DI water, and an HCl solution may be sequentially used and the sonication may be simultaneously performed.

The substrate may be a Ni base material and the Ni base material may be a Ni foam or Ni coin type.

As the sputter targets MoS₂ and Ni may be used. The sputter target MoS₂ may be a main structure material constituting an electrode and the sputter target Ni may be a doping material for forming a 1T structure with respect to the MoS₂ structure.

The sputter target Ni can ensure a 1T structure of an electrode through Ni doping and can improve adsorption with a Ni base material (Ni foam or Ni coin) that is usually used in alkaline water electrolysis, which can improve hydrogen adsorption energy for high hydrogen evolution reaction activity through the 1T structure and can activate an electrochemically inactive basal plane through Ni doping.

The sputter target MoS₂ and the sputter target Ni may be different in power supply type. For example, power may be supplied in an RF type for the sputter target MoS₂ and power may be supplied in a DC type for the sputter target Ni.

Further, power of the sputter target MoS₂ may be 100 to 300 W. Power of the sputter target Ni may be 5 to 50 W. Accordingly, the sputter target MoS₂ may form the main structure of an electrode and the sputter target Ni may be configured as a doping material.

The co-sputtering is performed as a process of single step, so it is possible to expect reduction of costs in manufacturing of an electrode, and simultaneously, it is possible to easily control the Ni doping amount by controlling power of a sputter target gun and it is possible to manufacture a large-area electrode.

Time for the simultaneous deposition may be 1 to 5 hours (hr).

Hereafter, the present disclosure is described in more detail through embodiments. The following embodiments are only examples for helping understand the present disclosure without limiting the present disclosure.

### EMBODIMENT

A nickel substrate (Ni foam) is prepared into a chamber, sonication is performed on the nickel substrate in 1 mole of KOH solution for 2 minutes (min) to remove an oxide film and impurities on the prepared substrate, the substrate is washed in DI water through sonication, the substrate is immersed in an HCl solution of 20 wt %, and then washed again in DI water through sonication (washing of substrate). The washed substrate is moved into a main chamber from the load lock chamber, pressure is set at ˜10⁻³ torr using a rotary chamber, and then a vacuum is produced at 5×10⁻⁶ torr using a turbo molecular pump (chamber vacummized). The inside of the chamber is set at a work pressure of 5×10⁻³ torr using a Baratron gauge by sending Ar gas at 50 sccm (chamber pressure set). Thereafter, MoSz (diameter: 4 inch, thickness: 14 inch, purity: 99.9%) and Ni (diameter: 4 inch, thickness: 2 mm, purity: 99.99%) are prepared as sputter targets, and then pre-sputtering is performed on the sputter targets at 100 W for MoS₂ and 10 W for Ni for 5 minutes (min) to remove impurities on the surfaces of the sputter targets and check production of plasma with the shield of the substrate closed (pre-sputtering). Thereafter, co-sputtering is performed at a pressure condition of 5×10⁻³ torr while maintaining the temperature of the substrate at 200° C. using a heater, a rotator is operated so that an electrode is uniformly deposited on the substrate, and MoS₂ and Ni are simultaneously deposited through RF output and DC output, respectively, under the sputtering conditions in the following Table 1, whereby a MOS₂/Ni electrode was manufactured (deposition of electrode).

### COMPARATIVE EXAMPLE

An electrode was manufactured under the conditions of the following Table 1 using only MOS₂ (diameter: 4 inch, thickness: ¼ inch, purity: 99.9%) by performing the same process as the above embodiment.

TABLE 1

| | | Chamber | | Substrate |
|---|---|---|---|---|
| | | pressure | Deposition | temperature |
| Items | Power (W) | (torr) | time (hr) | (° C.) |
| Comparative | RF(MoS₂) 100 | 5 × 10⁻³ | 1 | 200 |
| example | | | | |
| Embodiment 1 | RF(MoS₂) 100 | 5 × 10⁻³ | 1 | 200 |
| | DC(Ni) 5 | | | |
| Embodiment 2 | RF(MoS₂) 100 | 5 × 10⁻³ | 1 | 200 |
| | DC(Ni) 10 | | | |
| Embodiment 3 | RF(MoS₂) 100 | 5 × 10⁻³ | 1 | 200 |
| | DC(Ni) 50 | | | |
| Embodiment 4 | RF(MoS₂) 200 | 5 × 10⁻³ | 1 | 200 |
| | DC(Ni) 10 | | | |
| Embodiment 5 | RF(MoS₂) 300 | 5 × 10⁻³ | 1 | 200 |
| | DC(Ni) 10 | | | |
| Embodiment 6 | RF(MoS₂) 300 | 5 × 10⁻³ | 3 | 200 |
| | DC(Ni) 10 | | | |
| Embodiment 7 | RF(MoS₂) 300 | 5 × 10⁻³ | 5 | 200 |
| | DC(Ni) 10 | | | |

### Experimental Example 1. Analysis of Weight Ratio and Molar Ratio

The weight ratios and molar ratios of the electrodes manufactured in the embodiment and the comparative example were shown in the following Table 1.

TABLE 2

| | Weight ratio | Molar ratio |
|---|---|---|
| Items | (mg, MoS₂:Ni) | (μM, MoS₂:Ni) |
| Comparative | — | — |
| example | | |
| Embodiment 1 | 0.37:0.015 | 2.31:0.26 |
| | | (90:10) |
| Embodiment 2 | 0.37:0.03 | 2.31:0.51 |
| | | (82:18) |
| Embodiment 3 | 0.37:0.3 | 2.31:5.11 |
| | | (31:69) |
| Embodiment 4 | 0.74:0.03 | 4.62:0.51 |
| | | (90:10) |
| Embodiment 5 | 1.25:0.03 | 7.78:0.51 |
| | | (94:6) |
| Embodiment 6 | 1.25:0.03 | 7.78:0.51 |
| | | (94:6) |
| Embodiment 7 | 1.25:0.03 | 7.78:0.51 |
| | | (94:6) |

In Table 2, the weight ratio is the mass of each of MOS₂ and Ni deposited on the electrode manufactured in the embodiment using a Soda Limed Glass (SLG) substrate, and the molar ratio was calculated on the basis of 160.07 g/mo for MoS₂ and 58.69 g/mol for Ni.

### Experimental Example 2. Electrode Surface Structure Analysis According to Ni Output

Surface SEM images of electrodes manufactured under the output conditions of the sputter target Ni in the comparative example, embodiment 1, embodiment 2, and embodiment 3 are shown in FIG. 2. In FIG. 2, the electrode manufactured in the comparative example is indicted by “M100”, the electrode manufactured in the embodiment 1 is indicated by “M100N5”, the electrode manufactured in the embodiment 2 is indicated by “M100N10”, and the electrode manufactured in the embodiment 3 is indicated by “M100N50”.

Referring FIG. 2, it can be seen that the edge plane grows upward in the electrode manufactured by doping only MOS₂ in the comparative example.

On the other hand, it can be seen that the electrodes manufactured by simultaneously doping MoS₂ and Ni in the embodiments 1 to 3 have a surface structure in which the edge plan decreases and the basal plane is further exposed. However, it can be seen that higher power for the sputter target Ni collapses the MoS₂ structure, as in the embodiment 3. Accordingly, it can be seen that when the power for the sputter target Ni increases, the function of doping is substantially not achieved.

### Experimental Example 3. Electrode Surface Structure Analysis According to Output and Deposition Time of MOS₂

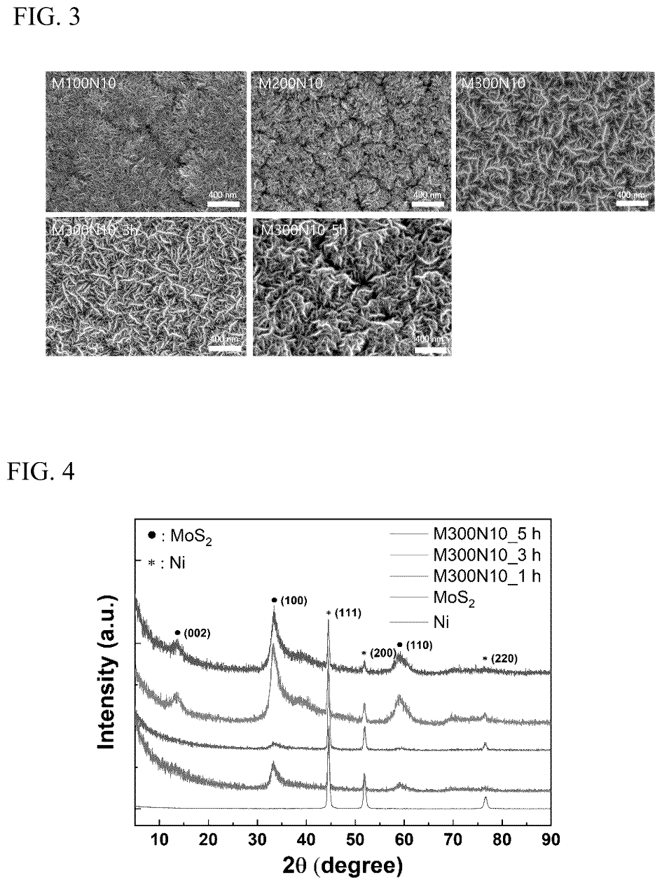

Expression SEM images of the electrodes manufactured under the output condition and the deposition time for a sputter target MoS₂ in the embodiment and embodiments 4 to 7 are shown in FIG. 3. In FIG. 3, the electrode manufactured in the embodiment 2 is indicated by “M100N10”, the electrode manufactured in the embodiment 4 is indicated by “M200N10”, the electrode manufactured in the embodiment 5 is indicated by “M300N10”, the electrode manufactured in the embodiment 6 is indicated by “M300N10_3h”, and the electrode manufactured in the embodiment 7 is indicated by “M300N10_5h”.

Further, an X-ray Diffraction (XRD) analysis result of the electrodes manufactured in the embodiments 5 to 7 is shown in FIG. 4. In FIG. 4, the electrode manufactured in the embodiment 5 is indicated by “M300N10”, the electrode manufactured in the embodiment 6 is indicated by “M300N10_3h”, the electrode manufactured in the embodiment 7 is indicated by “M300N10_5h”, and the XRD analysis result of MoS₂ and Ni is also shown.

Referring to the electrodes manufactured in the embodiments 2, 4, and 5 in FIG. 3, it can be seen that the higher the power of the sputter target MoS₂, the clearer the MoS₂ structure.

Referring to FIGS. 3A to 4, as in the electrodes manufactured in the embodiments 5 to 7, it can be seen that as the deposition time increases, the electrodes have a surface structure in which the portion of the basal plane is shown rather than the edge portion.

### Experimental Example 4. 1T Structure Analysis

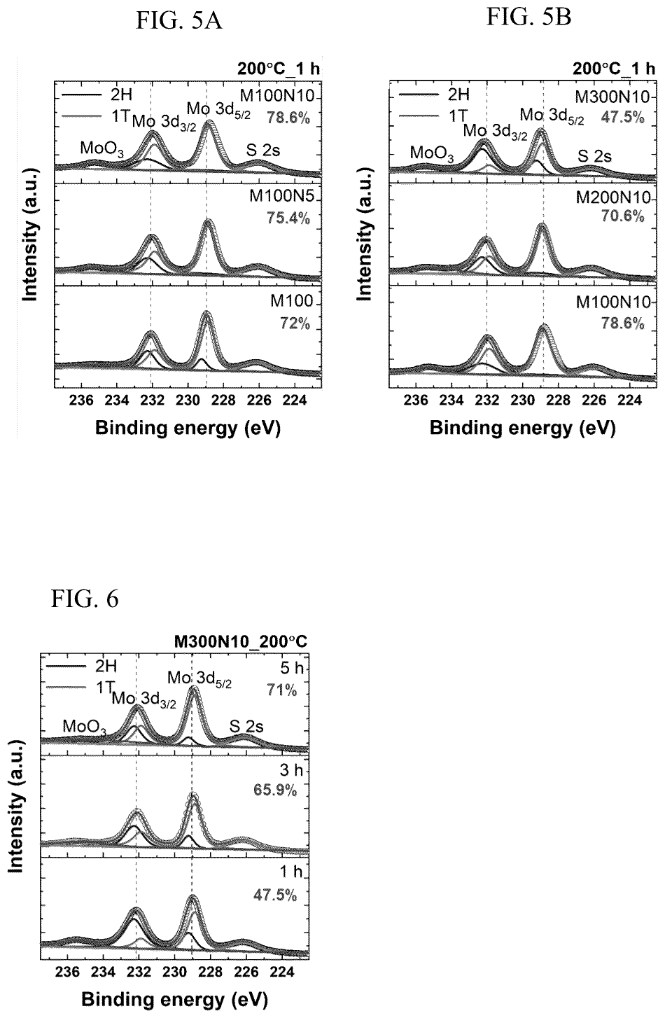

X-ray Photoelectron Spectroscopy (XPS) analysis was performed on the electrodes manufactured in the comparative example and the embodiments 1, 2, 4, and 5, and the analysis result is shown in FIGS. 5A and 5B.

In FIGS. 5A and 5B, the electrode manufactured in the comparative example is indicated by “M100”, the electrode manufactured in the embodiment 1 is indicated by “M100N5”, the electrode manufactured in the embodiment 2 is indicated by “M100N10”, the electrode manufactured in the embodiment 4 is indicated by “M200N10”, and the electrode manufactured in the embodiment 5 is indicated by “M300N10”, in which FIG. 5A shows the XPS analysis results of the electrodes manufactured in the comparative example and the embodiments 1 and 2 and FIG. 5B shows the XPS analysis results of the electrodes manufactured in the embodiments 2, 4, and 5.

Referring to FIG. 5A, it can be seen that the higher the power of the sputter target Ni (the higher the Ni doping amount), the higher the ratio of the 1T structure (72→78.6%) in the electrodes manufactured in the comparative example and the embodiments 1 and 2. Further, referring to FIG. 5B, it can be seen that the higher the power of the sputter target MoS₂, the lower the doping amount of Ni, so the ratio of the 1T structure decreases (78.6→47.5%) in the electrodes manufactured in the embodiments 2, 4, and 5.

X-ray Photoelectron Spectroscopy (XPS) analysis was performed on the electrodes manufactured in the embodiments 5 to 7, and the analysis result is shown in FIG. 6. In FIG. 6, the electrode manufactured in the embodiment 5 is indicated by “1h”, the electrode manufactured in the embodiment 6 is indicated by “3h”, and the electrode manufactured in the embodiment 7 is indicated by “5h”.

Referring to FIG. 6, it can be seen that when the deposition time increases, the time for which Ni influences MoS₂, that is, the time for which the 1T structure is formed increases, so the ratio of the 1T structure is increases again (47.5→71%) in the electrodes manufactured in the embodiments 5 to 7.

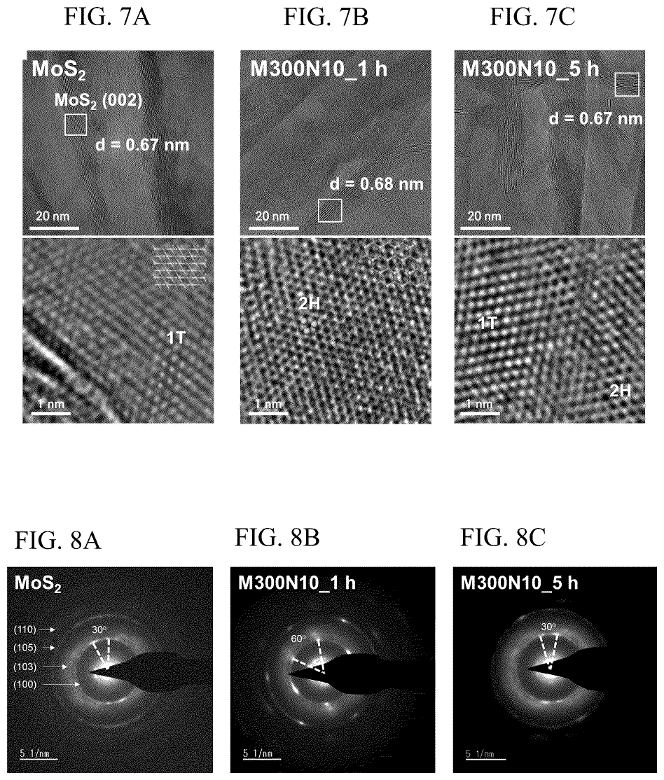

HR-TEM image analysis was performed on the electrodes manufactured in the comparative example and the embodiments 5 and 7, and the analyzed TEM image results are shown in FIGS. 7A to 7C. FIG. 7A is a TEM image of the electrode (“MOS₂”) manufactured in the comparative example, FIG. 7B is a TEM image of the electrode (“M300N10_1h”) manufactured in the embodiment 5, and FIG. 7C is a TEM image of the electrode (“M300N10_5h”) manufactured in the embodiment 7. In FIGS. 7A to 7C, the upper TEM images are entire TEM images and the lower TEM images are enlarged TEM images of the regions indicated by rectangles in the upper TEM Images.

Referring to FIGS. 7A to 7C, it can be seen that lattice fringes having an interplane distance of 0.67 to 0.68 nm corresponding to an MoS2 (002) crystal plane are observed in all of the electrodes manufactured in the comparative example and the embodiments 5 and 7. Referring FIG. 7A and FIG. 7C, it can be seen that a triangular Mo array of a high 1T yield is observed in the electrodes manufactured in the comparative example and the embodiment 7. Meanwhile, referring to FIG. 7B, it can be seen that Mo and S atom array of a honeycomb lattice is observed as 1T of low yield in the electrode manufactured in the embodiment 5.

Selected Area Electron Diffraction (SAED) pattern images of the electrode manufactured in the comparative example and the embodiments 5 and 7 were analyzed and are shown in FIGS. 8A to 8C. FIG. 8A is an SAED image of the electrode (“MOS₂”) manufactured in the comparative example, FIG. 8B an SAED image of the electrode (“M300N10_1h”) manufactured in the embodiment 5, and FIG. 8C is an SAED image of the electrode (“M300N10_5h”) manufactured in the embodiment 7.

Referring to FIGS. 8A to 8C, it can be seen that all of the electrodes manufactured in the comparative example and the embodiments 5 and 7 have a crystal plane with polycrystalline structures 100, 103, 105, and 110. Referring to FIG. 8B, it can be seen that a clear hexagonal spot pattern is observed in the crystal plane 100 in the 2H structure in the electrode manufactured in the embodiment 5. Referring to FIGS. 8A and 8C, it can be seen that additional spots forming an angle of 30° of another 2H spot are observed in structure with excellent 1T in the electrodes manufactured in the comparative example and the embodiment 7.

### Experimental Example 5. Electrochemical Surface Area (ECSA) Analysis

Electrochemical surface area (ECSA) analysis was performed through a three-electrode system, and in more detail, graphite was used for a counter electrode (CE), Hg/HgO was used for a reference electrode (RE), and the electrode manufactured in the above embodiment was used for a WE (work electrode, electrode reaction area 0.785 cm²). Electrolyte was 1M of KOH solution, an ECSA was measured at scan rates of 20, 40, 60, 80, 100 mV/s through cyclic voltammetry (CV) in a non-Faraday region ((−0.65 to −0.55 V vs Hg/Hg0, 0.273˜0.373 V VS RHE), the halves of the sum of redox current density at medium voltage (−0.6 V vs Hg/Hg0, 0.32 V vs RHE) of CV at respective scan rates were plotted in a scan rate vs current density graph, and then a slope was obtained through linear fitting (slope value was ECSA, mF/cm²).

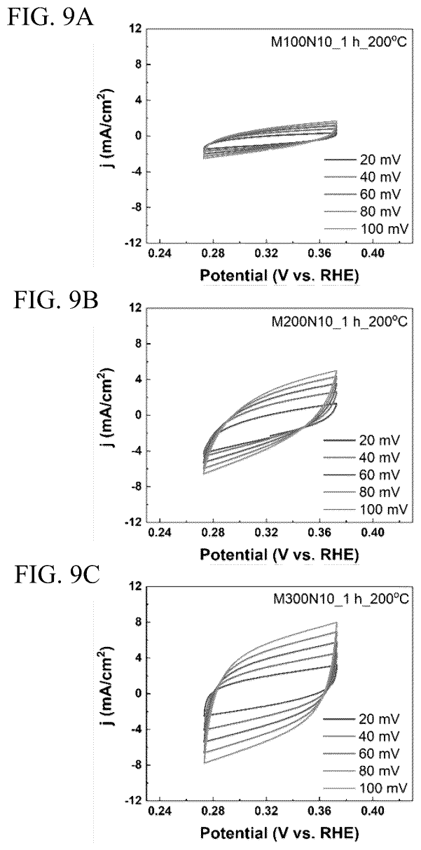

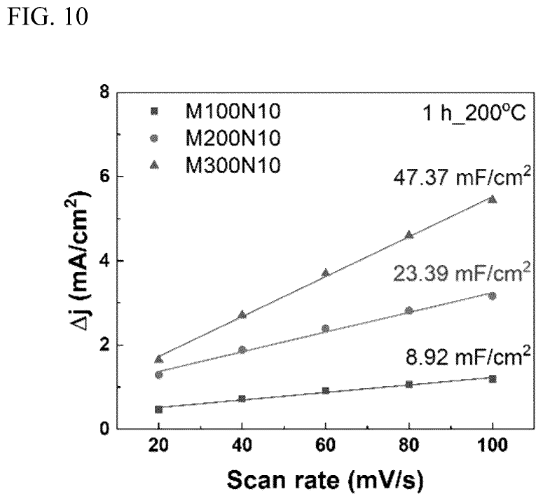

Electrochemical surface area (ECSA) analysis was performed on the electrodes manufactured in the embodiments 2, 4, and 5, and the analysis results are shown in FIGS. 9A to 10. FIGS. 9A to 9C show CV curves according to ECSA analysis and FIG. 10 shows current variation according to scan rates according to the analysis results shown in FIGS. 9A to 9C. FIG. 9A shows the ECSA analysis result of the electrode manufactured in the embodiment 2, FIG. 9B shows the ECSA analysis result the electrode manufactured in the embodiment 4, and FIG. 9C shows the ECSA analysis result of the electrode manufactured in the embodiment 5. In FIG. 10, the electrode manufactured in the embodiment 2 is indicated by “M100N10”, the electrode manufactured in the embodiment 4 is indicated by “M200N10”, and the electrode manufactured in the embodiment 5 is indicated by “M300N10”.

Referring to FIGS. 9A to 10, it can be seen that the higher the power of the sputter target MOS₂, the lower the concentration of the relative sputter target Ni, so the value of high C_{dl} (Double-layer Capacitance) decreases.

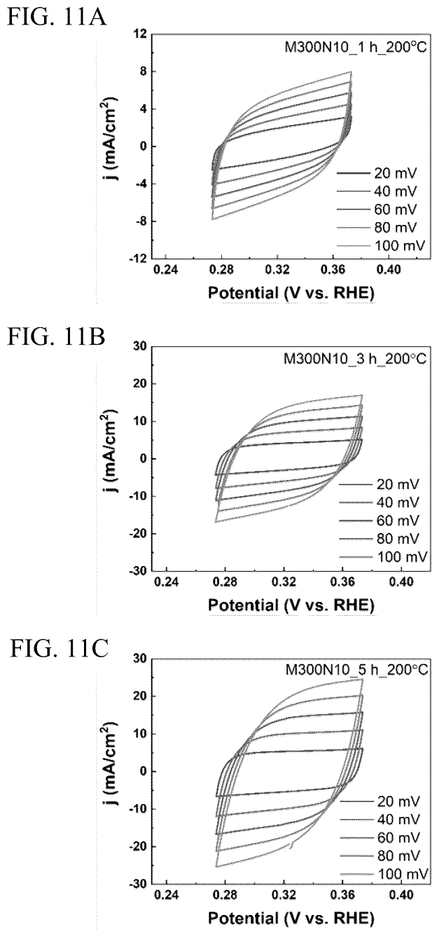

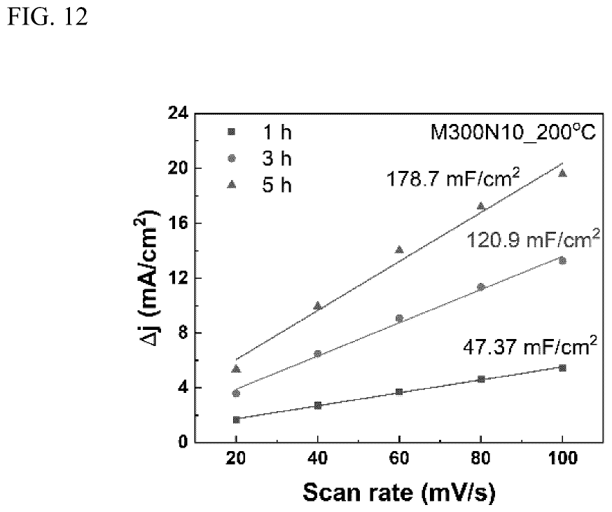

Electrochemical surface area (ECSA) analysis was performed on the electrodes manufactured in the embodiments 5 to 7, and the analysis results are shown in FIGS. 11A to 12. FIG. 11A shows the ECSA analysis result of the electrode manufactured in the embodiment 5, FIG. 11B shows the ECSA analysis result of the electrode manufactured in the embodiment 6, and FIG. 11C shows the ECSA analysis result of the electrode manufactured in the embodiment 7. In FIG. 12, the electrode manufactured in the embodiment 5 is indicated by “1h”, the electrode manufactured in the embodiment 6 is indicated by “3h”, and the electrode manufactured in the embodiment 7 is indicated by “5h”.

Referring to FIGS. 11A to 12, it can be seen that the longer the deposition time, the higher the high C_{dl} value.

### Experimental Example 6. Hydrogen Evolution Reaction (HER) Analysis

Hydrogen evolution reaction (HER) analysis was performed through a three-electrode system, and in more detail, graphite was used for a counter electrode (CE), Hg/HgO was used for a reference electrode (RE), and the electrode manufactured in the above embodiment was used for a WE (work electrode, electrode reaction area 0.785 cm²). Electrolyte was 1M of KOH solution and a polarization curve was plotted to current density of ˜−64 mA/cm² after measurement was performed at a scan rate of 5 mV/s in the ranges of −0.924 to −1.6 V vs Hg/HgO and 0 to 0.676 V vs RHE. In Tafel, a measured polarization curve was plotted for a log value of current density vs and overvoltage (a value of a polarization voltage in HER, ideal voltage of hydrogen evolution reaction was 0 V) and then Tafel slope was obtained using linear fitting. EIS was performed at −1.1 V vs Hg/Hg. and 0.176 V vs RHE to minimize the influence by hydrogen bubbles and measurement was performed within the range of 100 kHz˜0.1 Hz.

(1) HER Analysis According to Sputter Target Ni Power

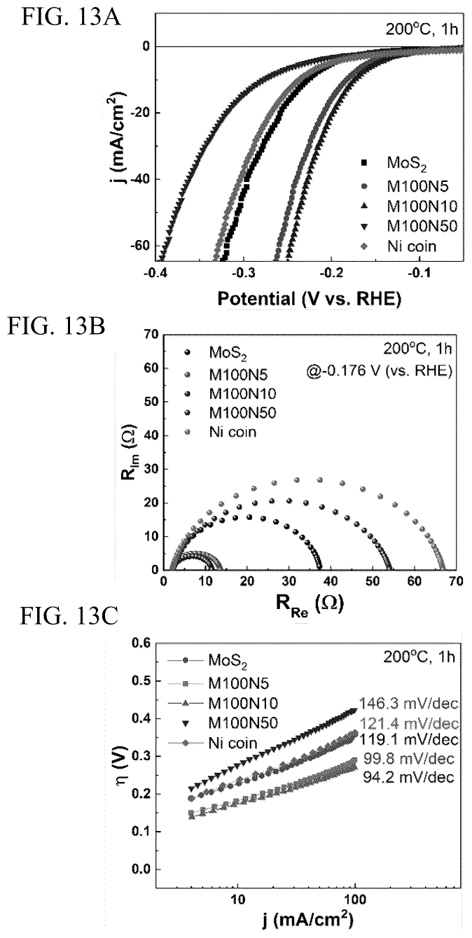

Hydrogen evolution reaction (HER) analysis was performed on the electrodes manufactured in the embodiments 1 to 3 and the analysis results are shown in FIGS. 13A to 13C. Hydrogen evolution reaction (HER) analysis results are shown in FIGS. 13A to 13C for MoS₂ and Ni coin that are comparative groups. FIG. 13A shows a polarization curve according to hydrogen evolution reaction, FIG. 13B shows a Nyquist plot, and FIG. 13C shows a Tafel plot. In FIGS. 13A to 13C, the electrode manufactured in the embodiment 1 is indicated by “M100N5”, the electrode manufactured in the embodiment 2 is indicated by “M100N10”, and the electrode manufactured in the embodiment 3 is indicated by “M100N50”.

Values of overvoltage η and charge transfer resistance R_{ct} are shown in the following Table 3 on the basis of the analysis results shown in FIGS. 13A to 13C.

TABLE 3

| | η (mV) | |
|---|---|---|
| | (@ 10 | |
| Items | mA/cm²) | R_{ct} (Ω) |
| MoS₂ | −227 | 35.17 |
| Embodiment 1 | −183 | 11.45 |
| Embodiment 2 | −173 | 9.464 |
| Embodiment 3 | −277 | 52.08 |
| Ni coin | −237 | 64.86 |

Referring to FIGS. 13A to 13C and Table 3, it can be seen that Ni doping and a high 1T yield influence hydrogen evolution reaction activity and charge transfer kinetics and it can be seen that appropriate concentration of Ni (power of sputter target Ni, embodiment 2) is important. Further, it can be seen that high Ni doping (embodiment 3) decreases hydrogen evolution reaction activity and charge transfer kinetics.

(2) HER Analysis According to Sputter Target MoS₂ Power

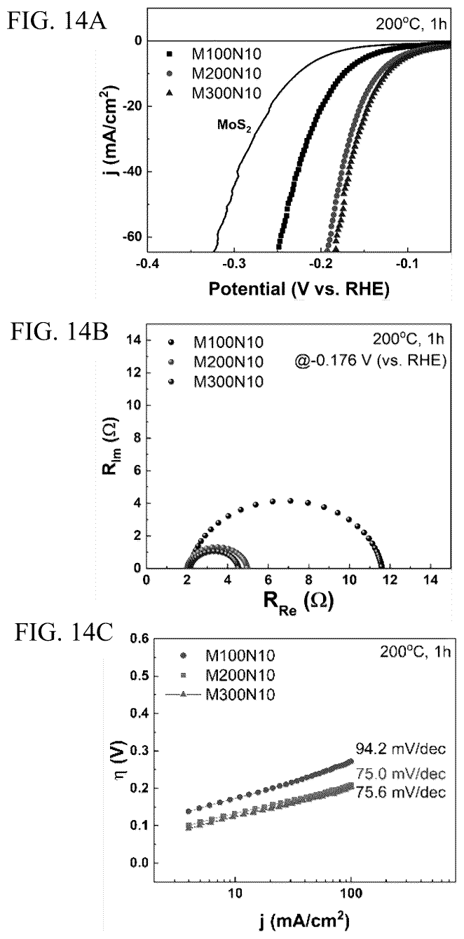

Hydrogen evolution reaction (HER) analysis was performed on the electrodes manufactured in the embodiments 2, 4, and 5 and the analysis results are shown in FIGS. 14A to 14C. FIG. 14A shows a polarization curve according to hydrogen evolution reaction, FIG. 14B shows a Nyquist plot, and FIG. 14C shows a Tafel plot. In FIG. 14A to 14C, the electrode manufactured in the embodiment 2 is indicated by “M100N10”, the electrode manufactured in the embodiment 4 is indicated by “M200N10”, and the electrode manufactured in the embodiment 5 is indicated by “M300N10”.

Values of overvoltage η and charge transfer resistance R_{ct} are shown in the following Table 4 on the basis of the analysis results shown in FIGS. 14A to 14C.

TABLE 4

| | η (mV) | |
|---|---|---|
| | (@ 10 | |
| Items | mA/cm²) | R_{ct} (Ω) |
| Embodiment 2 | −173 | 9.464 |
| Embodiment 4 | −133 | 2.962 |
| Embodiment 5 | −124 | 2.387 |

Referring to FIGS. 14A to 14C and Table 4, it can be seen that, at high sputter target MoS₂power (embodiments 2, 4, and 5), as the active surface area increases, the hydrogen evolution reaction activity and charge transfer kinetics increase even at a low 1T yield.

(3) HER Analysis According to Deposition Time

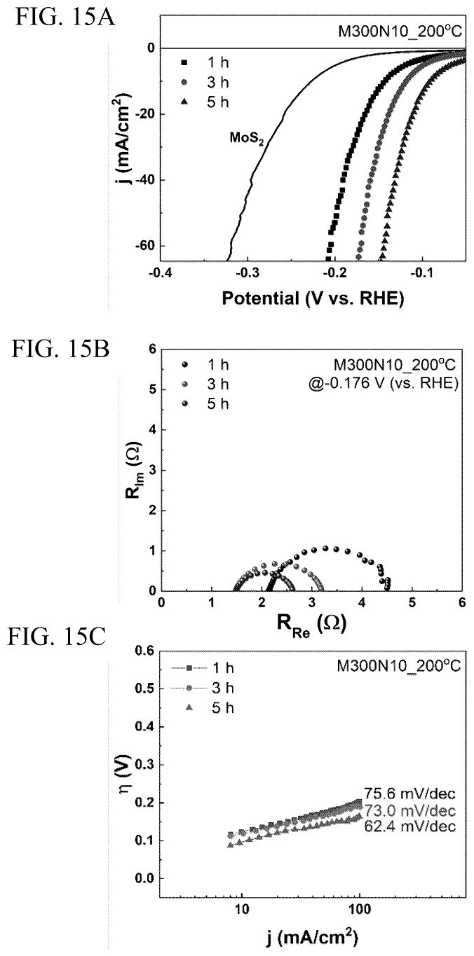

Hydrogen evolution reaction (HER) analysis was performed on the electrodes manufactured in the embodiments 5 to 7 and the analysis results are shown in FIGS. 15A to 15C. FIG. 15A shows a polarization curve according to hydrogen evolution reaction, FIG. 15B shows a Nyquist plot, and FIG. 15C shows a Tafel plot. In FIGS. 15A to 15C, the electrode manufactured in the embodiment 5 is indicated by “1h”, the electrode manufactured in the embodiment 6 is indicated by “3h”, and the electrode manufactured in the embodiment 7 is indicated by “7h”.

Values of overvoltage η and charge transfer resistance R_{ct} are shown in the following Table 5 on the basis of the analysis results shown in FIGS. 15A to 15C.

TABLE 5

| | η (mV) | |
|---|---|---|
| | (@ 10 | |
| Items | mA/cm²) | R_{ct} (Ω) |
| Embodiment 5 | −124 | 2.387 |
| Embodiment 6 | −119 | 1.723 |
| Embodiment 7 | −91 | 1.132 |

Referring to FIGS. 15A to 15C and Table 5, as the deposition time increases (embodiments 5 to 7), the electrodes have high 1T yield and active surface area, so hydrogen evolution reaction activity increases.

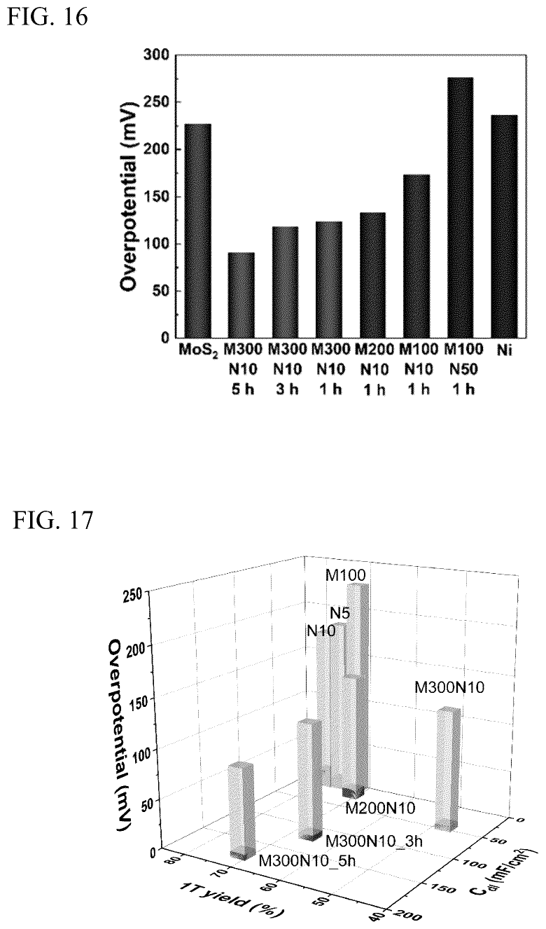

The overvoltages of the electrodes manufactured in the embodiments 2 to 7 according to the analysis shown in FIGS. 13A to 15C are shown in FIG. 16. In FIG. 16, on the x-axis, the electrode manufactured in the embodiment 2 is indicated by “M100N10_1h”, the electrode manufactured in the embodiment 3 is indicated by “M100N50_1h”, the electrode manufactured in the embodiment 4 is indicated by “M200N10_1h”, the electrode manufactured in the embodiment 5 is indicated by “M300N10_1h”, the electrode manufactured in the embodiment 6 is indicated by “M300N10_3h”, and the electrode manufactured in the embodiment 7 is indicated by “M300N10_5h”.

The 1T yield, Cal, and overvoltage (current density of 10 mA/cm²) of the electrodes manufactured in the comparative example and the embodiments 1, 2, and 4 to 7 according to the analysis shown in FIGS. 13A to 15C are shown in FIG. 17. In FIG. 17, the electrode manufactured in the comparative example is indicated by “M100”, the electrode manufactured in the embodiment 1 is indicated by “N5”, the electrode manufactured in the embodiment 2 is indicated by “N10”, the electrode manufactured in the embodiment 4 is indicated by “M200N10”, the electrode manufactured in the embodiment 5 is indicated by “M300N10”, the electrode manufactured in the embodiment 6 is indicated by “M300N10_3h”, and the electrode manufactured in the embodiment 7 is indicated by “M300N10_5h”.

### Application Example 1. Manufacturing of Single Cell

The electrode (base material Ni foam) manufactured in the embodiment 7 and having a size of 4.4×4.8 cm² was configured as a cathode, an Ni foam (4.4×4.8 cm²) as configured as an anode, Zirfon UPT 500 was used as a diaphragm, 400 kgf was applied as load cell pressure, electrolyte was 30 wt % of KOH, an electrolyte flow rate was 500 sccm, and electrolyte temperature was 80° C., whereby a single cell was manufactured.

### Application Example 2. Manufacturing of Single Cell

The same configuration as the application example 2 was applied and Ni—Fe LDH (4.4×4.8 cm²) was configured as an anode.

Comparative Group. Manufacturing of Single Cell

The same configuration as the application example 2 was applied and Ni foam (4.4×4.8 cm²) was configured as a cathode.

The configurations of the single cells according to the application example 1, the application example 2, and the comparative group are shown in the following Table 6.

TABLE 6

| | Cathode | Anode | Diaphragm |
|---|---|---|---|
| Application | Embodiment 7 | Ni foam | Zirfon UPT |
| example 1 | | | 500 |
| Application | Embodiment 7 | Ni—Fe LDH | Zirfon UPT |
| example 2 | | | 500 |
| Comparative | Ni foam | Ni foam | Zirfon UPT |
| group | | | 500 |

### Experimental Example 7. Analysis of Single Cell

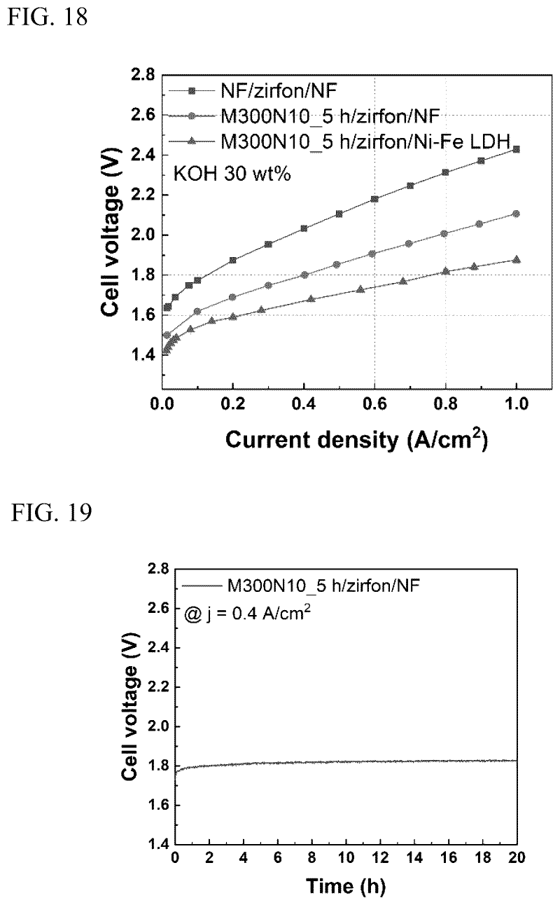

Cell voltages according to current density of the single cells manufactured in the application example 1, the application example 2, and the comparative group were measure and the measured results are shown in FIG. 18. In FIG. 18, the single cell manufactured in the application example 1 is indicated by “M300N10_5h/zifon/NF”, the single cell manufactured in the application example 2 is indicated by “M300N10_5h/zifon/Ni—Fe LDH”, and the single cell manufactured in the comparative group is indicated by “NF/zifon/NF”.

Referring to FIG. 18, it can be seen that the single cells manufactured in the application example 1 and the application example 2 are stably operated.

Cell voltage over time of the single cell manufactured in the application example 1 was measured while applying constant current of 0.4 A/cm², and the result is shown in FIG. 19. Referring to FIG. 19, it can be seen that stable cell voltage is maintained even though operation time passes.

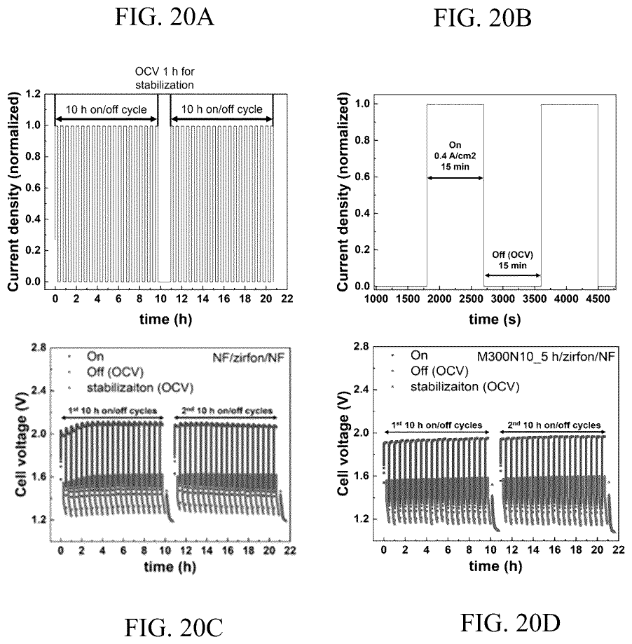

Dynamic operation performance evaluation according to on/off (start/stop) was performed on the single cell manufactured in the application example 1 and the result is shown in FIGS. 20A to 20D. Dynamic operation was 0.4 A/cm² in the case of start (power On) and operation was alternately performed at every 15 minutes (min) at open circuit voltage (OCV) in the case of OFF. Dynamic operation performance evaluation was performed with cycles of on/off of 10 hours the cycles were divided into a 1st on/off cycle and a 2nd on/off cycle, and a stabilization cycle of one hour was provided between the 1st on/off cycle and the 2nd on/off cycle. The current density range of the on/off cycles was based on 0˜1.0 A/cm², as in FIG. 20A, and start (On) (@0.4 A/cm²) and stop (Off) were each repeated at every 15 minutes (min), as in FIG. 20B.

FIG. 20C shows cell voltages of the single cell of the comparative group (NF/zirfon/NF) measured at the 1st on/off cycle and the 2nd on/off cycle. Referring to FIG. 20C, stabilization was made in some extent after the cell voltage greatly increased at the first 1st on/off cycle, but voltage increased by about 100 mV (deterioration of performance).

FIG. 20D shows cell voltages of the single cell of the application example 1 (M300N10_5h/zirfon/NF) measured at the 1st on/off cycle and the 2nd on/off cycle. Referring to FIG. 20D, it can be seen that voltage increased by 5 mV for the same time in start/stop, which means that when the electrode (M300N10_5h) of the embodiment 7 was used as a cathode, deterioration of performance at the start/stop dynamic operation was attenuated.

Although embodiments of the present disclosure were described above in detail, the spirit of the present disclosure is not limited thereto and the present disclosure may be changed and modified in various ways on the basis of the basic concept without departing from the scope of the present disclosure described in the following claims.

What is claimed is:

1. A method for manufacturing an electrode using co-sputtering, the method comprising:
preparing a substrate in a chamber;
preparing MoS₂ and Ni as sputter targets in the chamber;
pre-sputtering the sputter targets; and
simultaneously depositing the sputter targets on the substrate.

2. The method of claim 1, wherein the substrate is Ni foam or Ni coin.

3. The method of claim 1, wherein the sputter target MOS₂ and the sputter target Ni are different in power supply type.

4. The method of claim 3, wherein power is supplied in an RF type for the sputter target MOS₂, and
power is supplied in a DC type for the sputter target Ni.

5. The method of claim 1, wherein power of the sputter target MoS₂ is 100 to 300 W.

6. The method of claim 1, wherein power of the sputter target Ni is 5 to 50 W.

7. The method of claim 1, wherein time for the simultaneous deposition is 1 to 5 hours (hr).
